(19) United States
(12) Patent Application Publication
(10) Pub. No.: US 2016/0131719 A1
(43) Pub. Date: May 12, 2016

(54) BATTERY STATE DETECTION DEVICE

(71) Applicant: YAZAKI CORPORATION, Tokyo (JP)

(72) Inventor: Nobuyuki Takahashi, Shizuoka (JP)

(21) Appl. No.: 14/982,964

(22) Filed: Dec. 29, 2015

Related U.S. Application Data
(63) Continuation of application No. PCT/JP2014/068697, filed on Jul. 14, 2014.

(30) Foreign Application Priority Data
Jul. 17, 2013 (JP) 2013-148278

(51) Int. Cl. G01R 31/36; H01M 10/42

(52) U.S. Cl. CPC G01R 31/3662; H01M 10/4285

(57) ABSTRACT

A battery state detection device enabling a state of a secondary battery to be detected relatively easily and accurately is provided. In a battery state detection device, a μCOM detects a plurality of internal complex impedances corresponding to a plurality of discrete detection frequencies in a secondary battery, and detects an SOH of the secondary battery based on the plurality of detected internal complex impedances. The plurality of frequencies corresponding to the plurality of internal complex impedances detected by the μCOM are allocated to two partial frequency ranges respectively corresponding to a plurality of partial graphs showing states of a plurality of components of the secondary battery in a graph in which the internal complex impedances of the secondary battery in a predetermined frequency range are plotted on a complex plane.

### TECHNICAL FIELD

The present invention relates to a battery state detection device detecting a state of a secondary battery.

### BACKGROUND ART

For example, each of various vehicles such as an electric vehicle (EV) traveling with use of an electric motor and a hybrid electric vehicle (HEV) traveling with use of both an engine and the electric motor mounts thereon a secondary battery such as a lithium ion rechargeable battery and a nickel hydride rechargeable battery as a power source of the electric motor.

It is known that such a secondary battery deteriorates with repeated charging and discharging and gradually decreases a chargeable capacity (a current capacity, a power capacity, and the like) thereof. In the electric vehicle or the like using the secondary battery, the chargeable capacity is derived by detecting the degree of deterioration of the secondary battery to calculate a mileage for the secondary battery, lifetime of the secondary battery, and the like.

One of indices indicating the degree of deterioration of the secondary battery is an SOH (State of Health), which is a ratio of a current chargeable capacity to an initial chargeable capacity. It is known that this SOH correlates with an internal impedance of the secondary battery, and by deriving the internal impedance of the secondary battery, the SOH can be detected based on the internal impedance.

The internal impedance of the secondary battery can be derived, e.g., by applying an alternating-current signal having a uniform waveform to the secondary battery and referring to a reply thereof. An example of such a technique for detecting the internal impedance of the secondary battery is disclosed in Patent Literature 1 and the like.

### CITATION LIST

### Patent Literatures

Patent Literature 1: JP 2004-251625 A
Patent Literature 2: JP 2012-220199 A

### SUMMARY OF INVENTION

### Technical Problem

However, the SOH of the secondary battery is defined by combination of states of deterioration of respective components of the secondary battery such as a positive electrode, a negative electrode, and an electrolyte thereof. For example, in a configuration in which the internal impedance of the secondary battery is detected only at a specific frequency (e.g., 1000 Hz), a state of a specific part that reacts with the frequency relatively easily is detected mainly. Accordingly, this detection result does not show an entire state of the secondary battery accurately, which causes a problem of low detection accuracy.

Also, it is known that, by measuring internal complex impedances of the secondary battery in a predetermined frequency range and plotting the impedances on a complex plane, a graph in which partial graphs showing the states of the respective components of the secondary battery are connected (also referred to as a “Cole-Cole plot”) is obtained. By deriving an equivalent circuit of the secondary battery based on this graph, detection accuracy can be improved (refer to Patent Literature 2). However, measurement of the internal impedances is required as many times as the sufficient number of frequencies to draw such a graph, and it is difficult to derive the equivalent circuit of the secondary battery from this graph, to cause a problem in which the SOH or the like of the secondary battery cannot be detected easily and accurately.

An object of the present invention is to solve such problems. That is, an object of the present invention is to provide a battery state detection device enabling a state of a secondary battery to be detected relatively easily and accurately.

### Solution to Problem

As the result of concerted study of a graph in which internal complex impedances of a secondary battery measured in a predetermined frequency range are plotted on a complex plane, the present inventor and the like arrived at the present invention upon discovering that each of a plurality of partial graphs showing states of a plurality of components of the secondary battery in the graph shows the state of the same component before and after deterioration in a case of the same frequency.

To achieve the above object, the invention of a first aspect provides a battery state detection device detecting a state of a secondary battery, including: impedance detection unit detecting a plurality of internal impedances corresponding to a plurality of discrete frequencies in the secondary battery; and battery state detection unit detecting the state of the secondary battery based on the plurality of internal impedances detected by the impedance detection unit, wherein the plurality of frequencies are allocated to at least two or more out of a plurality of partial frequency ranges respectively corresponding to a plurality of partial graphs showing states of a plurality of components of the secondary battery in a graph in which internal complex impedances of the secondary battery in a predetermined frequency range are plotted on a complex plane.

In the invention of a second aspect according to the first aspect, the battery state detection unit is configured to detect the state of the secondary battery with use of at least either values of the internal impedances and difference values of the plurality of internal impedances in terms of the plurality of internal impedances.

In the invention of a third aspect according to the second aspect, the battery state detection unit weights either/both the values of the internal impedances or/and the difference values between the plurality of internal impedances for use in detection of the state of the secondary battery.

In the invention of a fourth aspect, the impedance detection unit is configured to detect as the plurality of internal impedances a plurality of internal complex impedances corresponding to the plurality of discrete frequencies in the secondary battery.

### Advantageous Effects of Invention

According to the aspect of the present invention according to the first aspect, the impedance detection unit detects the plurality of internal impedances corresponding to the plurality of discrete frequencies in the secondary battery, and the battery state detection unit detects the state of the secondary battery based on the plurality of internal impedances detected by the impedance detection unit. The plurality of frequencies are allocated to at least two or more out of the plurality of partial frequency ranges respectively corresponding to the plurality of partial graphs showing the states of the plurality of components of the secondary battery in the graph in which the internal complex impedances of the secondary battery in the predetermined frequency range are plotted on the complex plane. For this reason, the plurality of internal impedances detected by the impedance detection unit correspond to at least two or more partial frequency ranges. That is, the plurality of internal impedances show the states of at least two or more components of the secondary battery. Accordingly, by using the plurality of internal impedances, the states of the plurality of components of the secondary battery can be detected with use of only the plurality of relatively less and discrete internal impedances without detecting internal complex impedances over the predetermined frequency range of the secondary battery. Consequently, the state of the secondary battery can be detected relatively easily and accurately.

According to the aspect of the present invention according to the second aspect, the battery state detection unit is configured to detect the state of the secondary battery with use of at least either the values of the internal impedances and the difference values of the plurality of internal impedances in terms of the plurality of internal impedances. For this reason, each value of the internal complex impedance represents a distance from an origin (0) on the complex plane, and each difference value of the plurality of internal complex impedances is a distance therebetween or a quasi-value. By using these distances, the state of the secondary battery can be detected more easily.

According to the aspect of the present invention according to the third aspect, the battery state detection unit weights either/both the values of the internal impedances or/and the difference values between the plurality of internal impedances for use in detection of the state of the secondary battery. For this reason, a large weight is applied to a state of the secondary battery having a large influence while a small weight is applied to a state of the secondary battery having a small influence. By doing so, the state of the secondary battery can be detected more accurately.

According to the aspect of the present invention according to the fourth aspect, the impedance detection unit is configured to detect as the plurality of internal impedances the plurality of internal complex impedances corresponding to the plurality of discrete frequencies in the secondary battery. For this reason, since the internal complex impedance represents the shape of the partial graph of the aforementioned graph (that is, the state of the component of the secondary battery) more accurately than the magnitude of the internal impedance (that is, the distance from the origin (0) on the complex plane), for example, the state of the secondary battery can be detected more accurately than in a configuration using the magnitude of the internal impedance.

### BRIEF DESCRIPTION OF DRAWINGS

FIG. 1 illustrates a schematic configuration of a battery state detection device according to an embodiment of the present invention.

FIG. 2 schematically illustrates a graph in which internal complex impedances of a secondary battery in a predetermined frequency range are plotted on a complex plane.

FIG. 3 schematically illustrates an example of a waveform of second charging current to be output from a charging unit of the battery state detection device in FIG. 1.

FIG. 4 is a flowchart illustrating an example of charging processing to be executed by a control unit provided in the battery state detection device in FIG. 1.

FIG. 5 is a flowchart illustrating an example of impedance detection processing to be executed by the control unit provided in the battery state detection device in FIG. 1.

FIG. 6 is a graph in which the internal complex impedances of a commercially-available secondary battery actually measured in the predetermined frequency range are plotted on the complex plane.

### DESCRIPTION OF EMBODIMENTS

### First Embodiment

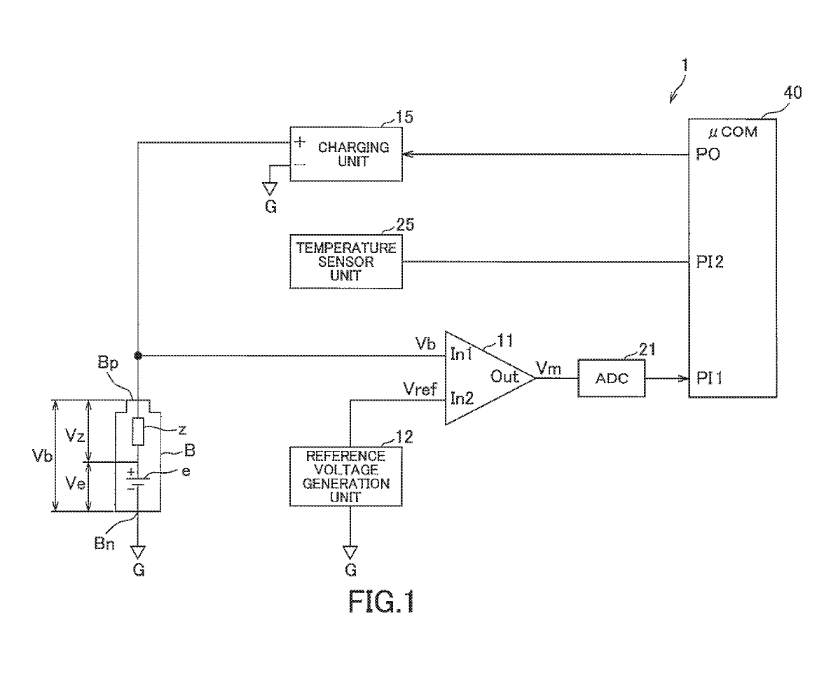

Hereinbelow, a battery state detection device according to a first embodiment of the present invention will be described with reference to FIGS. 1 to 6.

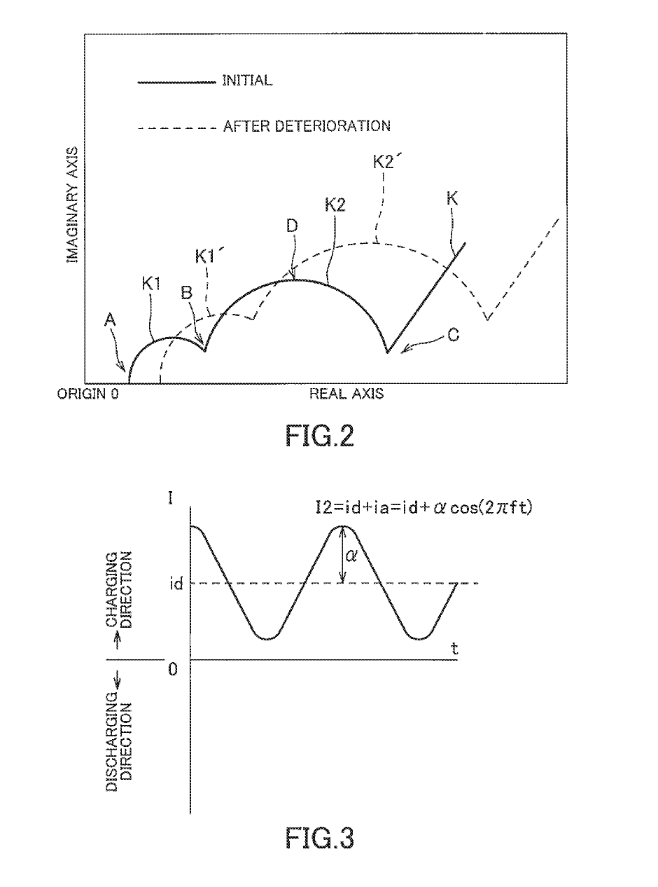

FIG. 1 illustrates a schematic configuration of a battery state detection device according to an embodiment of the present invention. FIG. 2 schematically illustrates a graph in which internal complex impedances of a secondary battery in a predetermined frequency range are plotted on a complex plane. FIG. 3 schematically illustrates an example of a waveform of second charging current to be output from a charging unit of the battery state detection device in FIG. 1.

The battery state detection device is mounted on an electric vehicle and is connected between electrodes of a secondary battery provided in the electric vehicle to detect as a state of the secondary battery an SOH (State of Health), which is a ratio of a current chargeable capacity to an initial chargeable capacity, for example. Other than this example, the battery state detection device may be installed in a vehicle power-feeding facility or the like, instead of being mounted on the electric vehicle, or may be applied to an apparatus, a system, or the like provided with the secondary battery other than the electric vehicle.

As illustrated in FIG. 1, a battery state detection device according to the present embodiment (illustrated with a reference sign 1 in the figure) detects the SOH of a secondary battery B mounted on a not-illustrated electric vehicle.

The secondary battery B includes an electromotive force unite generating voltage and an internal impedance Z. This internal impedance Z correlates with the SOH of the secondary battery B, and by deriving the internal impedance Z of the secondary battery B, the SOH can be detected based on the internal impedance Z.

By applying an alternating-current signal in a predetermined frequency range to the secondary battery B, internal complex impedances in the frequency range are obtained. When these internal complex impedances are plotted on a complex plane, a graph K called a Cole-Cole plot an example of which is schematically illustrated in FIG. 2 is obtained. This graph K is configured so that a partial graph K1 and a partial graph K2, which are arcs showing states of respective components of the secondary battery such as a positive electrode, a negative electrode, and an electrolyte thereof, are connected. In the example illustrated in FIG. 2, in the graph K, the partial graph K1 and the partial graph K2 show the state of the negative electrode and the state of the positive electrode, respectively.

When the degree of deterioration of the secondary battery changes, the respective partial graphs K1 and K2 change in size, approximately keeping similarity shapes (that is, arc shapes), into partial graphs K1′ and K2′. For example, the curvature of each arc changes, and the distance from an origin (0) of the complex plane changes. As the deterioration progresses, the curvature tends to decrease, and the distance from the origin (0) tends to increase. At this time, a partial frequency range containing a plurality of frequencies corresponding to the respective internal complex impedances constituting the partial graph K1 coincides with a partial frequency range containing a plurality of frequencies corresponding to respective internal complex impedances constituting the partial graph K1′. The same is true of the partial graph K2 and the partial graph K2′. That is, each of the partial graph K1 and the partial graph K1′ showing the state of the negative electrode is constituted by the plotted internal complex impedances contained in the same partial frequency range, and each of the partial graph K2 and the partial graph K2′ showing the state of the positive electrode is constituted by the plotted internal complex impedances contained in the same partial frequency range.

Accordingly, the state of the negative electrode of the secondary battery B can be detected based on the internal complex impedances corresponding to the frequencies contained in the partial frequency range corresponding to the partial graph K1, and the state of the positive electrode of the secondary battery B can be detected based on the internal complex impedances corresponding to the frequencies contained in the partial frequency range corresponding to the partial graph K2. By detecting the states of the plurality of components of the secondary battery B with use of these graphs, the state of the secondary battery B can be detected easily and accurately.

The battery state detection device according to the present embodiment detects the SOH of the secondary battery B by applying the aforementioned method.

As illustrated in FIG. 1, the battery state detection device according to the present embodiment (illustrated with the reference sign 1 in the figure) includes an amplifier 11, a reference voltage generation unit 12, a charging unit 15, an analog-digital converter 21, and a microcomputer 40 (hereinbelow referred to as a “μCOM 40”).

The amplifier 11 is an operational amplifier, for example, includes two input terminals (a first input terminal In1 and a second input terminal Int) and one output terminal (an output terminal Out), and outputs from the output terminal amplified voltage Vm derived by amplifying a difference value of voltage values input in these two input terminals at a predetermined gain G. A positive electrode Bp of the secondary battery B is connected to the first input terminal In1. An output of the below-mentioned reference voltage generation unit 12 is connected to the second input terminal Int. That is, the amplifier 11 outputs as the amplified voltage Vm voltage derived by multiplying a difference value of voltage Vb between electrodes of the secondary battery B and reference voltage Vref of the reference voltage generation unit 12 by the gain G. This gain G is set, e.g., in a range of from tens of times to tens of thousands of times, in accordance with the configuration of the battery state detection device 1, the kind of the secondary battery B, and the like. Alternatively, in a case in which no amplification is required, the gain G may be set to 1 (no amplification).

The reference voltage generation unit 12 is a voltage-dividing circuit including a plurality of resistors dividing power-supply voltage of the battery state detection device 1, or a Zener diode, for example, and outputs the constant reference voltage Vref to the amplifier 11.

The charging unit 15 is connected between the positive electrode Bp of the secondary battery B and reference potential G (that is, a negative electrode Bn of the secondary battery B) and is adapted to enable arbitrary charging current to flow into the secondary battery B at the time of charging the secondary battery B. The charging unit 15 is connected to the below-mentioned μCOM 40 and feeds the charging current to the secondary battery B in reaction to a control signal from the μCOM 40 to charge the secondary battery B. The charging unit 15 is equivalent to charging means.

The analog-digital converter 21 (hereinbelow referred to as the “ADC 21”) quantizes the amplified voltage Vm output from the amplifier 11 and outputs a signal representing a digital value corresponding to the amplified voltage Vm. In the present embodiment, the ADC 21 is implemented as a separate electronic component. However, the present invention is not limited to this, and an analog-digital conversion unit built in the below-mentioned μCOM 40 may be used, for example. In the present embodiment, an input allowable voltage range of the ADC 21 is 0 V to 5 V. It is to be understood that an ADC having another input allowable voltage range may be used.

A temperature sensor unit 25 includes a temperature detection element such as a thermistor and is configured to output a digital signal corresponding to a temperature detected by the temperature detection element. The temperature sensor unit 25 is arranged close to the secondary battery B to enable an atmospheric temperature around the secondary battery B to be detected. The temperature sensor unit 25 is connected to the below-mentioned μCOM 40 and outputs the signal representing the atmospheric temperature around the secondary battery B to the μCOM 40.

The μCOM 40 is configured to incorporate a CPU, a ROM, a RAM, and the like therein and controls the entirety of the battery state detection device 1. The ROM has pre-stored therein control programs adapted to cause the CPU to function as various means such as impedance detection unit and battery state detection unit, and the CPU executes these control programs to function as the various means. The ROM has stored therein information respectively indicating below-mentioned first charging current I1, below-mentioned second charging current I2, the gain G of the amplifier 11, an SOH detection temperature range W, and a switching determination value H, and this information is used to detect the SOH of the secondary battery B. In the present embodiment, the SOH detection temperature range W is set to 20° C.±1° C., and the switching determination value H is set to a median (2.5 V) of the input allowable voltage range of the ADC 21. Also, the reference voltage Vref and the gain G are set so that the amplified voltage Vm to be output from the amplifier 11 may be 2.5 V when the voltage Vb between the electrodes of the secondary battery B is a median of the voltage range of the secondary battery B (for example, in a case in which a lithium ion battery is used for the secondary battery B, and in which the voltage range thereof is 3.0 V to 4.2 V, a median thereof is 3.6 V, and this voltage value corresponds to 50% storing state (charging state) of the current chargeable capacity of the secondary battery B) in a state in which the first charging current I1 flows into the secondary battery B. It is to be understood that these values are illustrative only and are arbitrarily set in accordance with the configurations and the like of the battery state detection device and the secondary battery.

Also, the ROM of the μCOM 40 has stored therein information indicating a plurality of discrete detection frequencies f1, f2, and f3 to be set as frequencies of an alternating-current component is contained in the below-mentioned second charging current I2. Here, the term “discrete” means that the frequencies are not frequencies close to each other enough to enable the frequencies to be regarded as being consecutive in a predetermined frequency range for use in detection of the internal complex impedances of the secondary battery B. The plurality of detection frequencies f1, f2, and f3 are set in the following manner.

In an initial state of the secondary battery B, by applying an alternating-current signal in a predetermined frequency range to the secondary battery B, internal complex impedances in the frequency range are obtained. These internal complex impedances are plotted on a complex plane to obtain a graph (a Cole-Cole plot for the secondary battery B). Subsequently, in this graph, a plurality of partial graphs corresponding to a plurality of components of the secondary battery B are specified, and the detection frequencies f1, f2, and f3 are set to be allocated to a plurality of partial frequency ranges respectively corresponding to the plurality of partial graphs. Normally, in the aforementioned graph, a border of the plurality of partial graphs appears as a visually-identifiable characteristic point (a characteristic point). Examples of this characteristic point are an intersection point of an imaginary plane with a real axis and a point having large curvature (a tapered point). In the present embodiment, the graph K for the secondary battery B illustrated in FIG. 2 is obtained in advance by means of preliminary measurement, a simulation, or the like. In addition, based on this graph K, a frequency corresponding to a characteristic point A, which is an intersection point of the complex plane with the real axis, is set as the detection frequency f1, a frequency corresponding to a characteristic point B, which is a border between the partial graph K1 and the partial graph K2, is set as the detection frequency f2, and a frequency corresponding to a characteristic point C, which is a border of the partial graph K2 on an opposite side of the partial graph K1, is set as the detection frequency f3. It is to be understood that the present invention is not limited to this. The values for the detection frequencies f1, f2, and f3 are arbitrary as long as the detection frequencies f1, f2, and f3 are allocated to at least two partial frequency ranges without departing from the object of the present invention, such as setting a frequency corresponding to a middle point D of the partial graph K2 as the detection frequency f3. Meanwhile, since the aforementioned characteristic points A, B, and C appear at the same frequencies on the graph even in a case in which the secondary battery B not in the initial state is used, the detection frequencies f1, f2, and f3 may be set with use of the secondary battery B not in the initial state. Also, it can be thought that secondary batteries having the same configurations as each other have similar shapes of the graph K. Thus, for example, by deriving detection frequencies for one of a plurality of secondary batteries contained in one production lot, the same detection frequencies can be used for the other secondary batteries B in the production lot.

Also, the ROM of the μCOM 40 has stored therein information about a calculating formula or an information table enabling the SOH of the secondary battery to be obtained by substituting a plurality of internal complex impedances for the plurality of detection frequencies into the formula or the table.

The μCOM 40 includes an output port PO connected to the charging unit 15. The CPU of the μCOM 40 transmits the control signal to the charging unit 15 via the output port PO and controls the charging unit 15 so that the first charging current I1 containing only a predetermined direct-current component id (I1=id) and the second charging current I2 containing this direct-current component id and the sinusoidal alternating-current component ia having amplitude α equal to or less than a current value of the direct-current component id (I2=id+ia (ia=αcos (2πft), where α≦id)) may flow from the charging unit 15 into the secondary battery B. In the second charging current I2, since the amplitude of the alternating-current component ia is set to the current value of the direct-current component id or less, the first charging current I1 and the second charging current I2 will not be negative values (that is, a direction in which the secondary battery B is discharged) even when the alternating-current component ia shifts to a minimum value. That is, the second charging current I2 flows only in a charging direction, not in the discharging direction, as schematically illustrated in FIG. 3.

The μCOM 40 includes an input port PI1 into which a signal output from the ADC 21 is input and an input port PI2 into which a signal output from the temperature sensor unit 25 is input. The signal input into the input port PI1 is converted into information in a format that the CPU of the αCOM 40 can recognize and is sent to the CPU. The CPU of the αCOM 40 detects an alternating-current component va contained in the amplified voltage Vm based on the information. The CPU also detects internal complex impedances of the secondary battery B for the detection frequencies f1, f2, and f3 based on the alternating-current component va of the amplified voltage Vm and the alternating-current component is of the second charging current I2 and detects the SOH of the secondary battery B based on the plurality of internal complex impedances. Also, the signal input into the input port PI2 is converted into information in the format that the CPU of the αCOM 40 can recognize and is sent to the CPU. Prior to detection of the SOH of the secondary battery B, the CPU of the αCOM 40 detects an atmospheric temperature around the secondary battery B based on the information to determine whether or not the temperature is appropriate for detection of the SOH.

The αCOM 40 includes a not-illustrated communication port. This communication port is connected to a not-illustrated in-vehicle network (e.g., CAN (Controller Area Network)) and is connected to a display unit of a terminal device or the like for vehicle maintenance via the in-vehicle network. The CPU of the αCOM 40 transmits a signal indicating the detected SOH to the display unit via the communication port and the in-vehicle network and displays the SOH of the secondary battery B on this display unit based on the signal. Alternatively, the CPU of the αCOM 40 may transmit the signal indicating the detected SOH to a display unit of a combination meter or the like mounted on the vehicle via the communication port and the in-vehicle network and display the SOH of the secondary battery B on this display unit based on the signal.

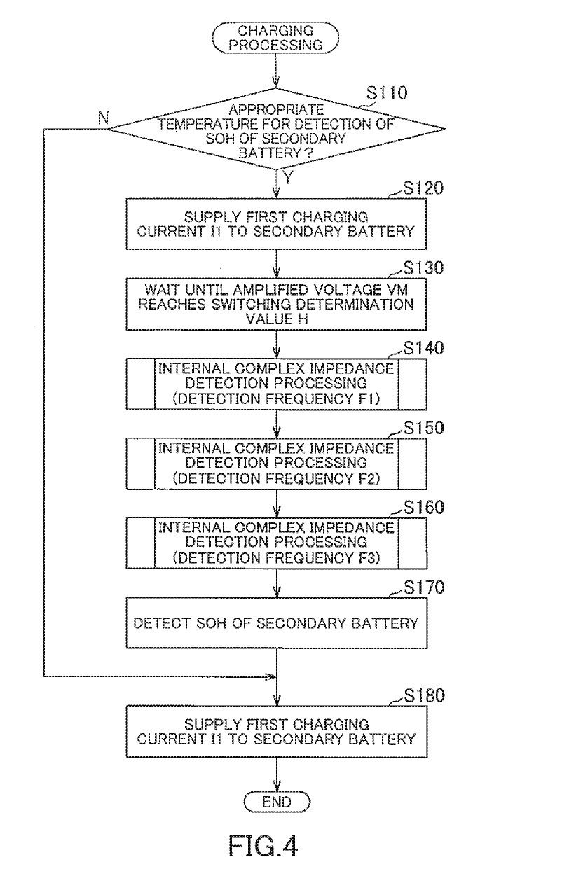

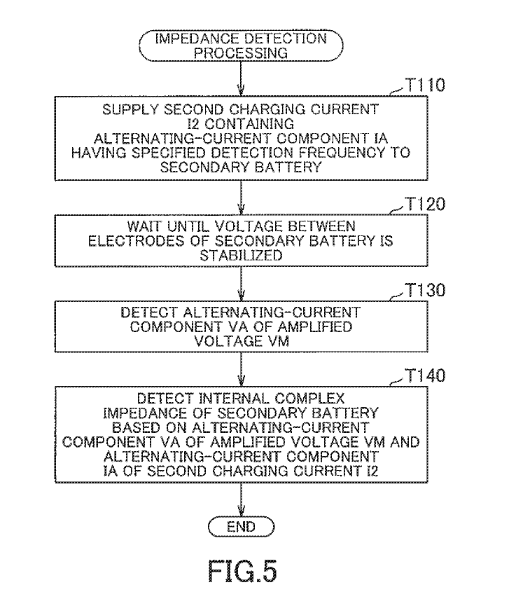

Next, an example of charging processing of the αCOM 40 provided in the aforementioned battery state detection device 1 will be described with reference to flowcharts in FIGS. 4 and 5.

FIG. 4 is a flowchart illustrating an example of charging processing to be executed by a control unit provided in the battery state detection device in FIG. 1. FIG. 5 is a flowchart illustrating an example of impedance detection processing to be executed by the control unit provided in the battery state detection device in FIG. 1.

When the CPU of the αCOM 40 (hereinbelow simply referred to as “the CPU”) receives a charging start command of the secondary battery B from an electronic control device mounted on the vehicle via the communication port, charging processing illustrated in FIG. 4 starts.

In the charging processing, it is first determined whether or not an atmospheric temperature around the secondary battery B is appropriate for detection of the SOH (S110). Specifically, the CPU detects the atmospheric temperature around the secondary battery B based on the information obtained from the signal input into the input port PI2 and determines whether or not the atmospheric temperature is in the SOH detection temperature range W, which is appropriate for detection of the SOH.

When it has been determined that the atmospheric temperature is not in the SOH detection temperature range W (N in S110), the first charging current I1 is caused to flow into the secondary battery B (S170). Specifically, the CPU transmits the control signal for charging with use of the first charging current I1 to the charging unit 15 via the output port PO. The charging unit 15 causes the first charging current I1 to flow into the secondary battery B in reaction to this control signal. As a result, charging of the secondary battery B is started. When the charging of the secondary battery B is thereafter finished, the charging processing ends.

On the other hand, when it has been determined that the atmospheric temperature is in the SOH detection temperature range W (Y in S110), the first charging current I1 is caused to flow into the secondary battery B (S120). Specifically, the CPU transmits the control signal for charging with use of the first charging current I1 to the charging unit 15 via the output port PO. The charging unit 15 causes the first charging current I1 containing only the predetermined direct-current component id to flow into the secondary battery B in reaction to this control signal. As a result, charging of the secondary battery B is started.

Subsequently, the CPU waits until the amplified voltage Vm to be output from the amplifier 11 reaches the switching determination value H (S130). That is, the CPU waits until the secondary battery B gets in a state of being charged up to a half (50%) of the capacity. Specifically, the CPU periodically (e.g., per second) detects the amplified voltage Vm to be output from the amplifier 11 based on the information obtained from the signal input into the input port PI1 to determine whether or not the amplified voltage Vm has reached the switching determination value H (2.5 V).

When the amplified voltage Vm reaches the switching determination value H, impedance detection processing illustrated in FIG. 5 is then executed plural times to detect a plurality of internal complex impedances for the detection frequencies f1, f2, and f3 in the secondary battery B (S140, S150, and S160).

In the impedance detection processing illustrated in FIG. 5, the second charging current I2 containing the alternating-current component ia having a specified detection frequency is first caused to flow into the secondary battery B (T110). Specifically, the CPU transmits the control signal for charging with use of the second charging current I2 to the charging unit 15 via the output port PO. The charging unit 15 causes the second charging current I2 containing the direct-current component id and the alternating-current component ia to flow into the secondary battery B in reaction to this control signal. Here, the frequency of the alternating-current component ia is set to the specified detection frequency.

Subsequently, the CPU waits until the voltage Vb between the electrodes of the secondary battery B is stabilized (T120). Specifically, when the charging current flowing into the secondary battery B is switched, the value of the voltage Vb between the electrodes of the secondary battery B fluctuates in a transient state and settles into a constant waveform. The CPU waits until pre-set voltage stabilization wait time (e.g., about 1 to 3 seconds) for the settling passes, and when this voltage stabilization wait time has passed, the voltage Vb between the electrodes of the secondary battery B settles into a constant waveform and is stabilized. In this present embodiment, conducting time of the second charging time 12 is set to be sufficiently short, or the value of the second charging time 12 is set to be sufficiently low, so that the secondary battery B may not be charged, and so that a charging state (that is, voltage Ve of the secondary battery B) may not change enough to influence detection of the internal complex impedances, even when the second charging current I2 flows into the secondary battery B.

Subsequently, the alternating-current component va of the amplified voltage Vm is detected (T130). Specifically, when the voltage Vb between the electrodes of the secondary battery B is stabilized (that is, after the elapse of the aforementioned voltage stabilization wait time), the CPU periodically samples and measures the amplified voltage Vm of the amplifier 11 based on the information obtained from the signal input into the input port P11 at least during a period of one cycle of the alternating-current component ia of the second charging current I2 or longer at intervals sufficiently shorter than the one cycle (as short intervals as to enable rough reproduction of the waveform of the alternating-current component ia, such as approximately 1/20 to 1/100 of the one cycle). This amplified voltage Vm contains a direct-current component vd and the alternating-current component va generated in accordance with the direct-current component id and the alternating-current component ia of the second charging current I2 (Vm=vd+va (va=βcos (2πft−θ), where θ is a phase difference from the alternating-current component ia of the second charging current I2).

Subsequently, the CPU detects the internal complex impedance of the secondary battery B based on the alternating-current component va of the amplified voltage Vm and the alternating-current component ia of the second charging current I2 (T140). The alternating-current component va and the alternating-current component ia are expressed as complex numbers in Formula (i) and Formula (ii) shown below:

va=βcos(2πft−θ)=Re[βe^{j(2}^{_{π}}^{ft-θ)}] (i)

ia=αcos(2πft)=Re[αe^{j(2π}^{_{π}}^{ft)}] (ii)

where Re [ ] indicates a real part.

Based on Formula (1) and Formula (2) shown above, an internal complex impedance z is derived by Formula (iii):

$$\begin{matrix}z = ( ( β / g ) \times ( {e}^{j ( 2 π ft - θ )} ) ) / ( α {e}^{j ( {2}_{π} ft )} ) \\ = ( ( β / G / α ) \times {e}^{- j θ}\end{matrix} \qquad ( iii )$$

where G indicates the gain of the amplifier 11.

The CPU detects the internal complex impedance z of the secondary battery B with use of Formula (iii) shown above.

Alternatively, in a simpler method, since the alternating-current component ia of the second charging current I2 is known, the internal complex impedance of the secondary battery B may be detected in which a value derived by dividing the alternating-current component va of the amplified voltage Vm when the alternating-current component ia is α (that is, α is a maximum value of ia, and at this time, 2πft=(π/2)×(2n−1), where n is a natural number) by the gain G is a real part, and in which a value derived by dividing the alternating-current component va of the amplified voltage Vm when the alternating-current component ia is 0 (that is, 0 is an intersection point with the time axis in FIG. 3, and at this time, 2πft=(π/2)×2n) by the gain G is an imaginary part.

The impedance detection processing ends, and the charging processing in FIG. 4 is restored. Hereinbelow, internal complex impedances corresponding to the detection frequencies f1, f2, and f3 are referred to as z1, z2, and z3, respectively.

After the plurality of internal complex impedances z1, z2, and z3 for the respective detection frequencies f1, f2, and f3 are detected, the SOH of the secondary battery B is detected based on the plurality of internal complex impedances z1, z2, and z3 (S170). Specifically, the CPU calculates a distance |OA| from the origin (0) to the point A, a distance |AB| from the point A to the point B, and a distance |BC| from the point B to the point C with use of the points A, B, and C representing the internal complex impedances z1, z2, and z3 detected in steps S140 to S160 plotted on the complex plane and substitutes these into the calculating formula of the SOH stored in the ROM to detect the SOH. In this calculating formula, predetermined weighting is applied to the distance |OA|, the distance |AB|, and the distance |BC|. An example of the calculating formula will be described below. Subsequently, the CPU transmits the detected SOH of the secondary battery B to another device or the like via the communication port.

Subsequently, the first charging current I1 is caused to flow into the secondary battery B again (S180). Specifically, the CPU transmits the control signal for charging with use of the first charging current I1 to the charging unit 15 via the output port PO. The charging unit 15 causes the first charging current I1 to flow into the secondary battery B in reaction to this control signal. As a result, charging of the secondary battery B is resumed. When the charging of the secondary battery B is thereafter finished, the charging processing ends.

Here, an example of the calculating formula for use in calculation of the SOH in step S170 of the aforementioned charging processing (Example 1) will be described.

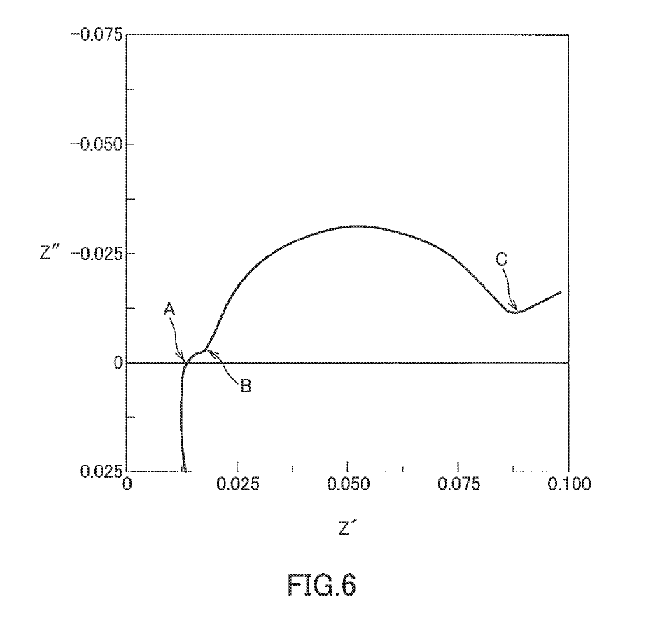

The inventor selected one secondary battery B out of a plurality of commercially-available secondary batteries of the same production lot (18650-series lithium ion batteries each having a ternary positive electrode and a graphite negative electrode). In an initial state of this secondary battery B, by applying an alternating-current signal in a predetermined frequency range to the secondary battery B, the inventor obtained internal complex impedances in the frequency range, plotted these internal complex impedances on a complex plane, and obtained a graph illustrated in FIG. 6 (a Cole-Cole plot for the secondary battery B). At this time, the charging state of the secondary battery B was 50%, and the atmospheric temperature was 20° C. Subsequently, the inventor visually detected the characteristic points A (an intersection point with the real axis), B, and C (points having large curvature) from this graph and set frequencies corresponding to these characteristic points A, B, and C as the detection frequencies f1 (500 Hz), f2 (30 Hz), and f3 (0.08 Hz).

Subsequently, the states of the plurality of secondary batteries were deteriorated by repeated charging and discharging (cycle deterioration), leaving under a high temperature in a fully charged state (high-temperature leaving deterioration), and the like. For each of the plurality of deteriorated secondary batteries B, (1) a current chargeable capacity was measured by charging from a fully discharged state to a fully charged state, and the current chargeable capacity was divided by an initial chargeable capacity to calculate the SOH based on the actual measurement, and (2) the internal complex impedances z1, z2, and z3 for the aforementioned detection frequencies f1, f2, and f3 were detected to calculate the distance |A|, the distance |AB|, and the distance |BC| (unit: mΩ) The results are shown in Table 1.

TABLE 1

| Deterioration | Measured | | | |
|---|---|---|---|---|
| Mode | SOH (%) | \|OA\| | \|AB\| | \|BC\| |
| Battery with No | 100 | 8.652 | 5.541 | 6.317 |
| Deterioration | | | | |
| High-Temperature | 94 | 10.809 | 4.472 | 21.745 |
| Leaving | 92 | 11.536 | 4.648 | 23.691 |
| Deterioration | 89 | 15.069 | 5.020 | 29.491 |
| | 86 | 16.990 | 5.791 | 30.183 |
| | 85 | 18.188 | 5.574 | 30.995 |
| | 80 | 21.597 | 6.389 | 37.394 |
| Cycle | 92 | 10.790 | 4.906 | 37.137 |
| Deterioration | 92 | 11.086 | 4.889 | 38.242 |
| | 90 | 10.618 | 4.844 | 43.702 |
| | 88 | 11.246 | 4.785 | 51.164 |
| | 85 | 12.076 | 4.840 | 58.241 |
| | 84 | 12.477 | 4.962 | 48.755 |
| | 81 | 12.231 | 4.739 | 57.104 |
| | 80 | 13.618 | 5.211 | 68.452 |

Subsequently, a multiple regression analysis was performed for each value in Table 1, and Formula (1) shown below, which was a calculating formula of the SOH, representing a correlation between the SOH and the distance |OA|, the distance |AB|, and the distance |BC|, was obtained.

$$SOH = 110.477353 - 0.986679 \times \vert OA \vert + 0 \times \vert AB \vert - 0.249165 \times \vert BC \vert \qquad ( 1 )$$

In Formula (1), the coefficients of the distance |OA|, the distance |AB|, and the distance |BC| are namely weighting coefficients. SOHs calculated by substituting the distance |OA|, the distance |AB|, and the distance |BC| shown in Table 1 into Formula (1) are shown in Table 2.

TABLE 2

| | | SOH Derived | SOH |
|---|---|---|---|
| Deterioration | Measured | from Formula | Difference |
| Mode | SOH (%) | (1) (%) | (%) |
| Battery with No | 100 | 100.37 | 0.37 |
| Deterioration | | | |
| High-Temperature | 94 | 94.39 | 0.39 |
| Leaving | 92 | 93.19 | 1.19 |
| Deterioration | 89 | 88.26 | −0.74 |
| | 86 | 86.19 | 0.19 |
| | 85 | 84.81 | −0.19 |
| | 80 | 79.85 | −0.15 |
| Cycle | 92 | 90.58 | −1.42 |
| Deterioration | 92 | 90.01 | −1.99 |
| | 90 | 89.11 | −0.89 |
| | 88 | 86.63 | −1.37 |
| | 85 | 84.05 | −0.95 |
| | 84 | 86.02 | 2.02 |
| | 81 | 84.18 | 3.18 |
| | 80 | 79.98 | −0.02 |

As shown in Table 2, by calculating the SOH with use of Formula (1), the SOH having an accuracy of ±4% or less in terms of the difference from the measured SOH can be calculated.

Detecting the SOH with use of an internal impedance corresponding to one frequency is equivalent to detecting the internal impedance with use of one of the distance |OA|, the distance |AB|, and the distance |BC| in Table 1, for example. For example, assume a case in which attention is focused on the distance |OA|. In Table 1, the battery having the measured SOH after the high-temperature leaving deterioration of 92% and the battery having the measured SOH after the cycle deterioration of 85% have the distance |OA| of 11.536 and 12.076, which are relatively close to each other, although they respectively have the SOH of 92% and 85%, which are quite different from each other. It is found that a detection accuracy of the SOH is lowered in the case of using only the distance |OA|. The same is true of the distance |AB| and the distance |BC|. This shows that, in the present invention, the SOH can be detected relatively accurately, and the SOH can be detected more accurately by weighting the respective values.

The CPU executing the processing in steps S140 to S160 in the flowchart in FIG. 4 (that is, the impedance detection processing in FIG. 5) functions as impedance detection unit, and the CPU executing the processing in step S170 functions as battery state detection unit.

Based on the above, according to the present embodiment, the impedance detection unit detects the plurality of internal complex impedances z1, z2, and z3 corresponding to the plurality of discrete detection frequencies f1, f2, and f3 in the secondary battery B, and the battery state detection unit detects the SOH of the secondary battery B based on the plurality of internal complex impedances z1, z2, and z3 detected by the impedance detection unit. The plurality of frequencies f1, f2, and f3 corresponding to the plurality of internal complex impedances z1, z2, and z3 detected by the impedance detection unit are allocated to the two partial frequency ranges respectively corresponding to the plurality of partial graphs K1 and K2 showing the states of the plurality of components of the secondary battery B in the graph K in which the internal complex impedances of the secondary battery B in the predetermined frequency range are plotted on the complex plane. For this reason, the plurality of internal complex impedances z1 and z2 detected by the impedance detection unit are contained in the partial frequency range corresponding to the partial graph K1 while the internal complex impedances z2 and z3 are contained in the partial frequency range corresponding to the partial graph K2. That is, the plurality of internal complex impedances z1, z2, and z3 show the states of two components of the secondary battery B. Accordingly, by using the plurality of internal complex impedances z1, z2, and z3, the states of the plurality of components of the secondary battery B can be detected with use of only the plurality of relatively less and discrete internal complex impedances z1, z2, and z3 without detecting internal complex impedances over the predetermined frequency range of the secondary battery B. Consequently, the SOH of the secondary battery B can be detected relatively easily and accurately. Also, since the internal complex impedance represents the shape of the partial graph of the aforementioned graph (that is, the state of the component of the secondary battery B) more accurately than the magnitude of an internal impedance (that is, the distance from the origin (0) on the complex plane), the SOH of the secondary battery B can be detected more accurately than in a configuration using the magnitude of the internal impedance.

Also, the battery state detection unit is configured to detect the SOH of the secondary battery B with use of values of the plurality of internal complex impedances z1, z2, and z3 and difference values of the plurality of internal complex impedances z1, z2, and z3 in terms of the plurality of internal complex impedances z1, z2, and z3. For this reason, the value of the internal complex impedance is the distance |OA| from the origin (0) on the complex plane, and the difference values of the plurality of internal complex impedances are the distance |AB| and the distance |BC| between the internal complex impedances. By using these distances, the SOH of the secondary battery B can be detected more easily.

Also, the battery state detection unit weights the value of the internal complex impedance and the difference values between the plurality of internal complex impedances for use in detection of the state of the secondary battery. For this reason, a large weight is applied to a state of the secondary battery B having a large influence while a small weight is applied to a state of the secondary battery B having a small influence. By doing so, the SOH of the secondary battery B can be detected more accurately.

### Second Embodiment

Hereinbelow, a battery state detection device according to a second embodiment of the present invention will be described.

In the battery state detection device according to the second embodiment, the SOH of the secondary battery B is detected with use of a value (magnitude) of an internal impedance instead of the internal complex impedance of the secondary battery B. Specifically, the second embodiment is similar to the first embodiment except that the processing for detecting the internal complex impedance of the secondary battery B (step 1140 in FIG. 5) and the processing for detecting the SOH of the secondary battery B (step S170 in FIG. 4) are different in the first embodiment. Thus, only different parts from those in the first embodiment will be described below.

In the aforementioned first embodiment, the SOH is detected with use of the distance |OA| from the origin (0) on the complex plane for the plurality of internal complex impedances z1, z2, and z3 corresponding to the detection frequencies f1, f2, and f3, and the distance |AB| and the distance |BC| between the internal complex impedances.

In the second embodiment described below, the SOH is detected with use of a plurality of internal impedances Z1, Z2, and Z3 corresponding to the detection frequencies f1, f2, and f3. That is, each internal complex impedance has a real part and an imaginary part, and these parts become coordinates on the complex plane. Conversely, the magnitude of each internal impedance represents a distance from the origin (0) to a coordinate position indicated by the internal complex impedance. When this is applied to the first embodiment, this is equivalent to detecting the SOH with use of the distance |OA|, a distance |OB|, and a distance |OC| from the origin. In FIG. 2, when ΔAOB and ΔBOC are obtuse triangles in which the angle OAB and the angle OBC are obtuse angles, approximation is established by |AB|≈|OB|−|OA| and |BC|≈|OC|−|OB|. In the second embodiment, instead of the distance |AB| and the distance |BC| between the internal complex impedances, a difference value |OB|−|OA| and a difference value |OC|−|OB|, which are approximate values to the distance |AB| and the distance |BC|, are used to detect the SOH.

In the second embodiment, the processing for detecting the internal complex impedance of the secondary battery B (step T140 in FIG. 5) is performed in the following manner.

In the preceding processing (step T130), the CPU detects a half value of a value derived by subtracting a minimum value from a maximum value of values for the amplified voltage Vm measured in a temporal sequence as amplitude β of the alternating-current component va of the amplified voltage Vm. Subsequently, the CPU divides the amplitude β of the alternating-current component va of the amplified voltage Vm by the gain G of the amplifier 11, divides the solution by the amplitude α of the alternating-current component ia of the second charging current I2, and detects the solution as the internal impedance Z of the secondary battery B (z=(β/G)/α).

Consequently, the internal impedances Z1, Z2, and Z3 of the secondary battery B corresponding to the detection frequencies f1, f2, and f3 are detected.

Also, in the second embodiment, the processing for detecting the SOH of the secondary battery B (step S170 in FIG. 4) is performed in the following manner.

The aforementioned internal impedances Z1, Z2, and Z3 show the distances from the origin (0) to the aforementioned points A, B, and C on the complex plane. That is, the internal impedances Z1, Z2, and Z3 show the distance OA, a distance |OB|, and a distance |OC|, respectively. Instead of the distance |AB| and the distance |BC| substituted into the calculating formula in the first embodiment, the value derived by subtracting the distance |OA| from the distance |OB| (|OB|−|OA|) and the value derived by subtracting the distance |OB| from the distance |OC| (|OC|−|OB|) are used to detect the SOH of the secondary battery B.

An example of the calculating formula for use in calculation of the SOH in this configuration (Example 2) will be described.

In a similar manner to that in Example 1 described above, the inventor selected one secondary battery B out of a plurality of commercially-available secondary batteries of the same production lot (18650-series lithium ion batteries each having a ternary positive electrode and a graphite negative electrode). In an initial state of this secondary battery B, by applying an alternating-current signal in a predetermined frequency range to the secondary battery B, the inventor obtained internal complex impedances in the frequency range, plotted these internal complex impedances on a complex plane, and obtained a graph illustrated in FIG. 6 (a Cole-Cole plot for the secondary battery B). At this time, the charging state of the secondary battery B was 50%, and the atmospheric temperature was 20° C. Subsequently, the inventor visually detected the characteristic points A (an intersection point with the real axis), B, and C (points having large curvature) from this graph and set frequencies corresponding to these characteristic points A, B, and C as the detection frequencies f1 (500 Hz), f2 (30 Hz), and f3 (0.08 Hz).

As illustrated in FIG. 6, the characteristic points A, B, and C are arranged around the real axis on the complex plane in order in a direction of the real axis. Here, consider a case in which the characteristic points A, B, and C are located on the real axis. In this case, the value derived by subtracting the distance |OA| from the distance |OB| (|OB|−|OA|) is equivalent to the distance |AB|, and the value derived by subtracting the distance |OB| from the distance |OC| (|OC|−|OB|) is equivalent to the distance |BC|. Thus, as illustrated in FIG. 6, in a configuration in which the characteristic points A, B, and C are arranged around the real axis on the complex plane in order in the direction of the real axis (that is, ΔAOB and ΔBOC are obtuse triangles in which the angle OAB and the angle OBC are obtuse angles), the value derived by subtracting the distance |OA| from the distance |OB| (|OB|−|OA|) and the value derived by subtracting the distance |OB| from the distance |OC| (|OC|−|OB|) can be used as approximate values to the distance |AB| and the distance |BC|.

Subsequently, the states of the plurality of secondary batteries were deteriorated by repeated charging and discharging (cycle deterioration), leaving under a high temperature in a fully charged state (high-temperature leaving deterioration), and the like. For each of the plurality of deteriorated secondary batteries B, (1) a current chargeable capacity was measured by charging from a fully discharged state to a fully charged state, and the current chargeable capacity was divided by an initial chargeable capacity to calculate the SOH based on the actual measurement, and (2) the internal complex impedances z1, z2, and z3 for the aforementioned detection frequencies f1, f2, and f3 were detected to calculate the distance |OA|, the distance |OB|, and the distance |OC|, and |OB|−−|OA| and |OC|−|OB|, which were difference values of these distances (unit: mΩ) The results are shown in Table 3.

TABLE 3

| Deterioration | Measured | | | |
|---|---|---|---|---|
| Mode | SOH (%) | \|OA\| | \|OB\| − \|OA\| | \|OC\| − \|OB\| |
| Battery with No | 100 | 8.652 | 4.894 | 6.273 |
| Deterioration | | | | |
| High-Temperature | 94 | 10.809 | 3.303 | 21.729 |
| Leaving | 92 | 11.536 | 3.561 | 23.675 |
| Deterioration | 89 | 15.069 | 4.140 | 29.482 |
| | 86 | 16.990 | 5.182 | 30.167 |
| | 85 | 18.188 | 4.912 | 30.987 |
| | 80 | 21.597 | 5.419 | 37.392 |
| Cycle | 92 | 10.790 | 3.823 | 37.082 |
| Deterioration | 92 | 11.086 | 3.591 | 38.188 |
| | 90 | 10.618 | 3.766 | 43.656 |
| | 88 | 11.246 | 3.665 | 51.134 |
| | 85 | 12.076 | 3.803 | 58.227 |
| | 84 | 12.477 | 3.876 | 48.730 |
| | 81 | 12.231 | 3.680 | 57.091 |
| | 80 | 13.618 | 4.186 | 68.447 |

Subsequently, a multiple regression analysis was performed for each value in Table 3, and Formula (2) shown below, which was a calculating formula of the SOH, representing a correlation between the SOH and the distance |OA|, the difference value |OB|−|OA|, and the difference value |OC|−|OB|, was obtained.

$$SOH = 110.46 - 0.99 \times \vert OA \vert + 0 \times ( \vert OB \vert - \vert OA \vert ) - 0.25 \times ( \vert OC \vert - \vert OB \vert ) \qquad ( 2 )$$

In Formula (2), the coefficients of the distance |OA|, the difference value |OB|−|OA|, and the difference value |OC|−|OB| are namely weighting coefficients. SOHs calculated by substituting the distance |OA|, the difference value |OB|−|OA|, and the difference value |OC|−|OB| shown in Table 3 into Formula (2) are shown in Table 4.

TABLE 4

| | | SOH Derived | SOH |
|---|---|---|---|
| Deterioration | Measured | from Formula | Difference |
| Mode | SOH (%) | (2) (%) | (%) |
| Battery with No | 100 | 100.33 | 0.33 |
| Deterioration | | | |
| High-Temperature | 94 | 94.33 | 0.33 |
| Leaving | 92 | 93.12 | 1.12 |
| Deterioration | 89 | 88.17 | −0.83 |
| | 86 | 86.10 | 0.10 |
| | 85 | 84.71 | −0.29 |
| | 80 | 79.73 | −0.27 |
| Cycle | 92 | 90.51 | −1.49 |
| Deterioration | 92 | 89.94 | −2.06 |
| | 90 | 89.03 | −0.97 |
| | 88 | 86.54 | −1.46 |
| | 85 | 83.95 | −1.05 |
| | 84 | 85.92 | 1.92 |
| | 81 | 84.08 | 3.08 |
| | 80 | 79.87 | −0.13 |

As shown in Table 4, by calculating the SOH with use of Formula (2), the SOH having an accuracy of ±4% or less in terms of the difference from the measured SOH can be calculated. This shows that, in the present invention, the SOH can be detected relatively accurately, and the SOH can be detected more accurately by weighting the respective values.

In this manner, in the second embodiment using the mere internal impedance instead of the internal complex impedance of the secondary battery B, similar effects to those of the aforementioned first embodiment can be obtained, and since the mere internal impedance is easier to detect than the internal complex impedance, the SOH of the secondary battery B can be detected more easily.

Although the preferred embodiments of the present invention have been described above, the battery state detection device according to the present invention is not limited to the configurations of these embodiments.

For example, although the battery state detection device is configured to detect the SOH of one secondary battery B in the aforementioned embodiments, the present invention is not limited to this. For example, the aforementioned battery state detection device may be provided at a tip thereof with a multiplexer, and by switching the multiplexer, the battery state detection device may be connected to a plurality of secondary batteries B and detect the respective SOHs of the plurality of secondary batteries B.

It is to be noted that the aforementioned embodiments are illustrative only, and that the present invention is not limited to the embodiments. That is, those skilled in the art can carry out the present invention by modifying the present invention in various ways without departing from the spirit of the present invention in accordance with conventionally known discoveries. Such modification shall still be included in the scope of the present invention as long as the modification has the configuration of the battery state detection device according to the present invention.

### REFERENCE SIGNS LIST

1 Battery state detection device
11 Amplifier
12 Reference voltage generation unit
15 Charging unit
21 Analog-digital converter
25 Temperature sensor unit
40 Microcomputer (impedance detection unit, battery state detection unit)
B Secondary battery
Bp Positive electrode of secondary battery
Bn Negative electrode of secondary battery
Vm Amplified voltage
G Gain
e Electromotive force unit
A, B, C Characteristic point
f1, f2, f3 Detection frequency (a plurality of discrete frequencies)
z1, z2, z3 Internal complex impedance

1. A battery state detection device detecting a state of a secondary battery, comprising:
an impedance detection unit detecting a plurality of internal impedances corresponding to a plurality of discrete frequencies in the secondary battery; and
a battery state detection unit detecting the state of the secondary battery based on the plurality of internal impedances detected by the impedance detection unit,
wherein the plurality of frequencies are allocated to at least two or more out of a plurality of partial frequency ranges respectively corresponding to a plurality of partial graphs showing states of a plurality of components of the secondary battery in a graph in which internal complex impedances of the secondary battery in a predetermined frequency range are plotted on a complex plane,
wherein the battery state detection unit uses values of the internal impedances, difference values between the plurality of internal impedances, or both of the values after being weighted, for use in detection of the state of the secondary battery.

2. The battery state detection device according to claim 1, wherein the impedance detection unit is configured to detect as the plurality of internal impedances a plurality of internal complex impedances corresponding to the plurality of discrete frequencies in the secondary battery.

3. The battery state detection device according to claim 1, wherein the battery state detection unit is configured to detect the state of the secondary battery with use of the values of the internal impedances and the difference values of the plurality of internal impedances in terms of the plurality of internal impedances.

4. The battery state detection device according to claim 2, wherein the battery state detection unit is configured to detect the state of the secondary battery with use of the values of the internal impedances and the difference values of the plurality of internal impedances in terms of the plurality of internal impedances.
